(19) United States
(12) Patent Application Publication
(10) Pub. No.: US 2017/0082701 A1
(43) Pub. Date: Mar. 23, 2017

(54) METHOD FOR CALCULATING THE CHANGE OF TEMPORAL SIGNALS

(71) Applicant: MAGQU CO. LTD., New Taipei City (TW)

(72) Inventors: Shieh-Yueh Yang, New Taipei City (TW); Yen-Fu Lee, New Taipei City (TW); Ming-Hung Hsu, New Taipei City (TW)

(73) Assignee: MAGQU CO. LTD., New Taipei City (TW)

(21) Appl. No.: 14/857,685

(22) Filed: Sep. 17, 2015

(51) Int. Cl. G01R 33/12

(52) U.S. Cl. CPC G01R 33/1276

(57) ABSTRACT

The present invention relates to a method for calculating the change of signals starting from the originally detected temporal signals (_102 ), comprising the following steps: (a) eliminating the drift in the originally detected temporal signals with time to get χᵢ signals; (b) removing the xi signals existing outside the range of 80% to 120% of the averaged value of all the χᵢ signals to get residual signals as x ₂ signals; (c) dividing the χ₂ signals into 14-100 sections; (d) finding the averaged value of the χ₂ signals in each section to get χ₃ signals; (e) optionally neglecting one or two of the first χ₃ signals and selecting six to nine χ₃ signals with the smallest value of standard deviation in initial sections, wherein the initial sections are the first one-fourth part to half part of all sections; (f) eliminating the drift in the selected χ₃ signals of step (e) with time to get χ₄ signals; (g) selecting six to nine χ₃ signals with the smallest value of standard deviation in terminal sections, wherein the terminal sections are the last one-fourth part to half part of all sections; (h) eliminating the drift in the selected χ₃ signals of step (g) with time to get χ₅ signals; and (i) finding the difference between the mean values of the χ₄ and χ₅ signals.

### FIELD OF THE INVENTION

The present invention relates to processes of calculating the change of temporal signals, especially for immunomagnetic reduction signals.

### BACKGROUND OF THE INVENTION

Researchers have demonstrated the feasibility of assaying bio-molecules using antibody functionalized magnetic nanoparticles, so-called magnetically labeled immunoassay (MLI) (H. C. Yang, L. L. Chiu, S. H. Liao, H. H. Chen, H. E. Horng, C. W. Liu, C. I. Liu, K. L. Chen, M. J. Chen, and L. M. Wang, Relaxation of biofunctionalized magnetic nanoparticles in ultra-low magnetic fields, J. Appl. Phys. 113, 043911 (2013)). In MLI, the magnetic signals related to the concentrations of target bio-molecules are detected. Several kinds of magnetic signals have been detected, such as nuclear magnetic resonance, magnetic relaxation, magnetic remenance, saturated magnetization, ac magnetic susceptibility, etc. The focus of the present invention is the assay technology so-called immunomagnetic reduction (IMR) (C. C. Yang, S. Y. Yang, H. H. Chen, W. L. Weng, H. E. Horng, J. J. Chieh, C. Y. Hong, and H. C. Yang, Effect of molecule-particle binding on the reduction in the mixed-frequency alternating current magnetic susceptibility of magnetic bio-reagents, J. Appl. Phys. 112, 024704 (2012)), which mechanism is briefly introduced below.

In IMR, the reagent is a solution having homogeneously dispersed magnetic nanoparticles, which are coated with hydrophilic surfactants and bio-probe (e.g. antibodies). Under external ac magnetic fields, magnetic nanoparticles oscillate with ac magnetic fields via magnetic interaction. Thus, the reagent under external ac magnetic fields shows a magnetic property, called ac magnetic susceptibility χ_{ac}, as illustrated in FIG. 1A. Via the bio-probes on the outmost shell, magnetic nanoparticles associate with and magnetically label bio-molecules (e.g. antigens) to be detected. Due to the association, magnetic nanoparticles become either larger, as schematically shown in FIG. 1B. The response of these larger magnetic nanoparticles to external ac magnetic fields is much less than that of originally individual magnetic nanoparticles. Thus, the χ_{ac} of the reagent is reduced due to the association between magnetic nanoparticles and detected bio-molecules. This is why the method is referred as ImmunoMagnetic Reduction. The ac magnetic susceptibility of reagent before nanoparticle-bio-molecule associations is usually referred as to χ_{ac,o}, while the ac magnetic susceptibility of reagent after nanoparticle-bio-molecule associations is referred as to χ_{ac,φ}. In principle, when more amounts of to-be-detected bio-molecules are mixed with a reagent, more magnetic nanoparticles become larger. A larger reduction in χ_{ac} could be expected for reagents. Such expectation has been demonstrated experimentally (C. C. Yang, S. Y. Yang, C. S. Ho, J. F. Chang, B. H Liu, and K. W. Huang, Development of antibody functionalized magnetic nanoparticles for the immunoassay of carcinoembryonic antigen: a feasibility study for clinical use, J. Nanobiotechnol. 12, 44 (2014)). In the present invention, a method is developed to quantify the reduction signal from the originally detected temporal χ_{ac} signals after mixing the reagent with a sample.

### BRIEF DESCRIPTION OF THE DRAWINGS

FIG. 1A: The ac magnetic susceptibility of reagent before nanoparticle-bio-molecule associations.

FIG. 1B: The ac magnetic susceptibility of reagent after nanoparticle-bio-molecule associations.

FIG. 2: Time dependent ac magnetic susceptibility χ_{ac} of reagent mixing with a detected sample.

FIG. 3: Time dependent ac magnetic susceptibility χ_{ac,2} of reagent mixing with a detected sample.

FIG. 4: Time dependent ac magnetic susceptibility χ_{ac,3} of reagent mixing with a detected sample.

FIG. 5: Time dependent ac magnetic susceptibility χ_{ac,4} and χ_{ac,5} of reagent at initials and terminals after mixing with a detected sample.

### SUMMARY OF THE INVENTION

The present invention relates to a method for calculating the change of signals starting from the originally detected temporal signals (χ), comprising the following steps: (a) eliminating the drift in the originally detected temporal signals with time to get χ₁ signals; (b) removing the xi signals existing outside the range of 80% to 120% of the averaged value of all the χ₁ signals to get residual signals as χ₂ signals; (c) dividing the χ₂ signals into 14-100 sections; (d) finding the averaged value of the χ₂ signals in each section to get χ₃ signals; (e) optionally neglecting one or two of the first χ₃ signals and selecting six to nine χ₃ signals with the smallest value of standard deviation in initial sections, wherein the initial sections are the first one-fourth part to half part of all sections; (f) eliminating the drift in the selected χ₃ signals of step (e) with time to get χ₄ signals; (g) selecting six to nine χ₃ signals with the smallest value of standard deviation in terminal sections, wherein the terminal sections are the last one-fourth part to half part of all sections; (h) eliminating the drift in the selected χ₃ signals of step (g) with time to get χ₅ signals; and (i) finding the difference between the mean values of the χ₄ and χ₅ signals.

### DETAILED DESCRIPTION OF THE INVENTION

The present invention provides a method for calculating the change of signals starting from the originally detected temporal signals (χ), comprising the following steps: (a) eliminating the drift in the originally detected temporal signals with time to get χ₁ signals; (b) removing the xi signals existing outside the range of 80% to 120% (or 90% to 110%) of the averaged value of all the χ₁ signals to get residual signals as χ₂ signals; (c) dividing the χ₂ signals into 14-100 sections; (d) finding the averaged value of the χ₂ signals in each section to get χ₃ signals; (e) optionally neglecting one or two of the first χ₃ signals and selecting six to nine χ₃ signals with the smallest value of standard deviation in initial sections, wherein the initial sections are the first one-fourth part to half part of all sections; (f) eliminating the drift in the selected χ₃ signals of step (e) with time to get χ₄ signals; (g) selecting six to nine χ₃ signals with the smallest value of standard deviation in terminal sections, wherein the terminal sections are the last one-fourth part to half part of all sections; (h) eliminating the drift in the selected χ₃ signals of step (g) with time to get χ₅ signals; and (i) finding the difference between the mean values of the χ₄ and χ₅ signals.

In an embodiment, the temporal signals are time dependent ac magnetic signals. In an embodiment, the change of signals is the reduction in ac magnetic susceptibility of materials. In an embodiment, the steps of eliminating the drift in the signals with time are done by subtracting each signal by the value lying in the correspondingly linear function.

### EXAMPLES

The examples below are non-limiting and are merely representative of various aspects and features of the present invention.

### Example 1

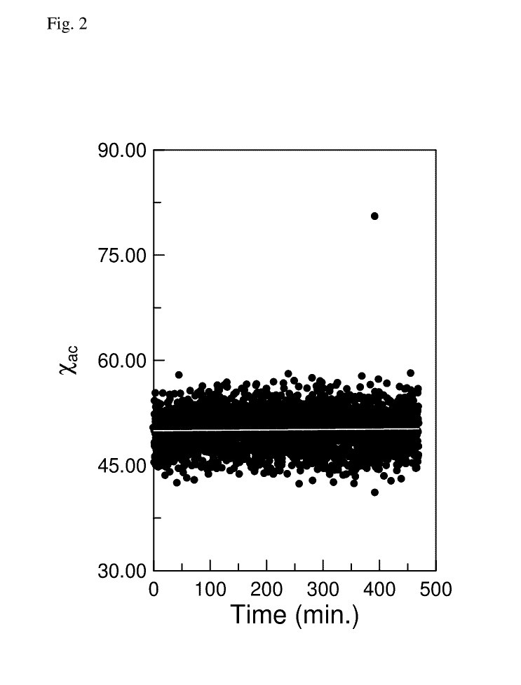

One of the IMR assays was given. The magnetic nanoparticles each encompassed a Fe₃O₄ core and coated with dextran. Antibodies against carcinoembryonic antigen (CEA), which was a biomarker for the risk evaluation of colorectal cancer, were immobilized onto magnetic nanoparticles via covalent binding between antibodies and dextran. The mean diameter of magnetic nanoparticles was 53 nm. Antibody-functionalized magnetic nanoparticles were dispersed in pH-7.4 phosphate buffered saline (PBS) solution to form the reagent for IMR. The magnetic concentration of the reagent was 8-mg-Fe/ml. The to-be-detected bio-molecule in this example was carcinoembryonic antigen (CEA). The CEA concentration of the test sample was 2.5 ng/ml. 40-μl reagent was mixed with 60-μl sample for the IMR measurement. The reader of IMR measurement was a magnetically labeled immuno-analyzer (XacPro-E, MagQu) to record the time dependent ac magnetic susceptibility of reagent after being mixed with the sample. The time dependent ac magnetic susceptibility, i.e. χ_{ac}-t curve, of reagent was shown in FIG. 2

It should be noted that bio-molecules can not bind with nanoparticles at the same instant. Instead, bio-molecules finish binding with nanoparticles during a period of time. Hence, the ac magnetic susceptibility χ_{ac} of reagent gradually decreased during the association period of time.

In FIG. 2, most of χ_{ac}'s were distributed between 45 and 52. The variations in temporal χ_{ac} masked the reduction in the ac magnetic susceptibility of reagent due to the nanoparticle-bio-molecule associations. Thus, the reduction in the ac magnetic susceptibility of reagent was not so obvious. In addition, some points were extremely high or low, which might be caused with ambient noises. Such signals were not true and should be removed. Moreover, the χ_{ac} in FIG. 2 might drift with time once the temperature around reagent raised or went down. In order to find the true reduction in the ac magnetic susceptibility of reagent due to the nanoparticle-bio-molecule associations, the effects of the signal variation, the ambient noise and temperature drift on the χ_{ac} of reagent must be removed. Therefore, a method was developed to be applied in this work to remove these effects and to find the true reduction in the χ_{ac} of reagent, as described below.

First of all, the drift in the detected χ_{ac} signals of reagent with time shown in FIG. 2 due to the temperature drift was eliminated via

χ_{ac,1}=χ_{ac}−s×t (Equation 1),

where s denoted the slope of the time dependence of the detected χ_{ac} signals of reagent shown in FIG. 2, t is time. The s in Equation 1 was obtained by fitting the time dependent detected χ_{ac} signals in FIG. 2 to a linear function. The slope of the linear function was s. The fitted linear function was plotted with the dashed line in FIG. 2. The slope of the fitted linear function in FIG. 2 was 5.88×10⁻⁴. Thus, the drift in χ_{ac} with time due to temperature drift around reagent was eliminated.

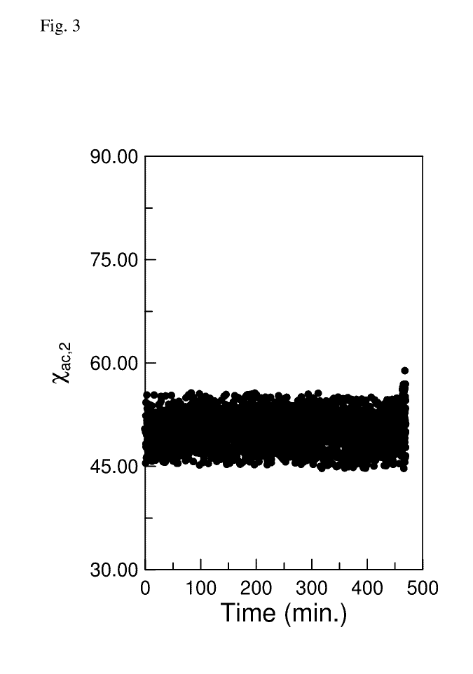

Secondly, the χ_{ac,1}'s far from the averaged value of temporal χ_{ac,1} were removed to neglect some points extremely high or low caused with ambient noises. For example, the χ_{ac,1}'s lower than 0.9 <χ_{ac,1}> and higher than 1.1 <χ_{ac,1}> were removed, where <χ_{ac,1}> was the averaged value of temporal χ_{ac,1}. The resultant time dependent χ_{ac} signals of reagent were shown in FIG. 3. The χ_{ac} signal of reagent was now denoted with χ_{ac,2}.

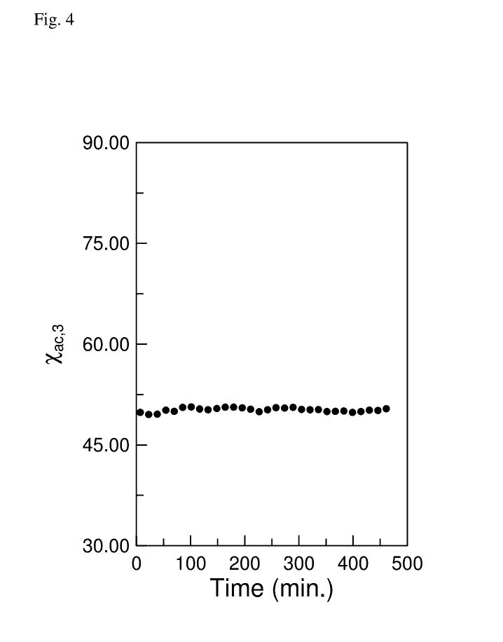

The time dependent χ_{ac,2} in FIG. 3 showed a reduction after 300 minutes. However, the χ_{ac,2} signals showed variations between 45 and 52. Such variation was mainly due to the noises of analyzer, and could be suppressed by averaging χ_{ac,2} within a suitable time interval. Thus, the third step was to suppress the variations in χ_{ac,2} by averaging χ_{ac,2}'s with a suitable time interval. For example, the whole period of detecting time was divided into m sections. The numbers nᵢ of χ_{ac,2} signal points in the ith section were

$${n}_{i} = [ N / m ] + {f}_{i} \\ with {f}_{i} = \{ \begin{matrix}1 , i \leq N \% m \\ 0 , i > N \% m\end{matrix} , \qquad ( Equation 2 )$$

where N was the total numbers of χ_{ac,2}, [ ] denoted Floor function, and N % m was the residue of N divided by m. For the case in FIG. 3, the N was 2916. All the χ_{ac,2} signals were divided into 30 sections, i.e. m=30. In case, i=1 to 30. Thus, the numbers of χ_{ac.2} signal points in the first to the sixth section were 98, and were 97 in the other sections. Then, the averaged value of χ_{ac,2} signals in each section was calculated. The time-evolution averaged χ_{ac,2} signal, denoted as χ_{ac,3}, in each section was plotted in FIG. 4.

The data points at initials in FIG. 4 denoted the ac magnetic susceptibility of reagent before the association between nanoparticles and to-be-detected biomolecules. Whereas, the data points at terminals in FIG. 4 corresponded to the ac magnetic susceptibility of reagent after the association between nanoparticles and to-be-detected biomolecules. Thus, the data points at initials and terminals in FIG. 4 were interested.

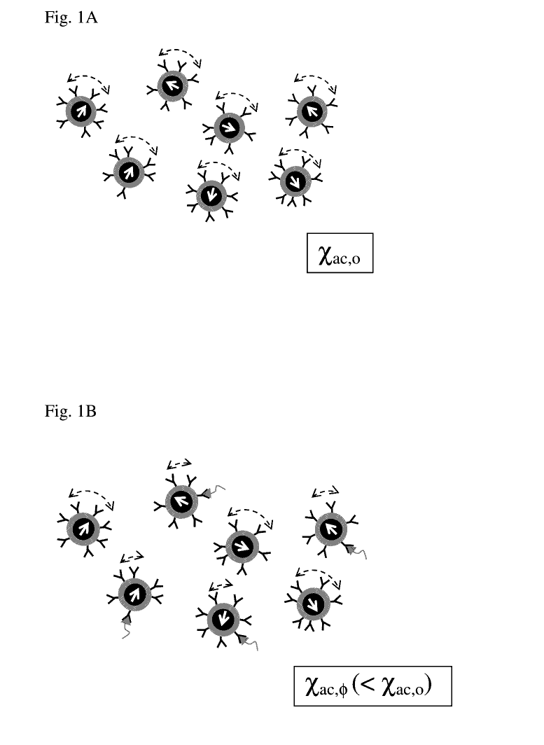

The fourth step was to select χ_{ac,3} signals at initial sections. To do this, several χ_{ac,3} signals were picked up at initials. The initial sections were the first one-fourth part to half part of all sections. Optionally, one or two of the first χ_{ac,3} signals would be neglected due to the initial un-stability of the measurement, and the following X_{ac,3} signals at initials were taken into account. Then, some picked χ_{ac,3} signals, which led to higher standard deviation of these picked χ_{ac,3} signals, would be neglected. The mean value of the residual χ_{ac,3} signals at initials was calculated as the χ_{ac,o} in FIG. 1. For example, two of the first χ_{ac,3} signals in FIG. 4 were neglected and the following eleven χ_{ac,3} signals were pick up. Then, the standard deviations of ten of the eleven χ_{ac,3} signals were calculated by sequentially neglecting one χ_{ac,3} signal. In this case, 11 values for the standard deviations were gotten. The χ_{ac,3} signal which would lead to the highest value of the standard deviations was removed. Thus, the ten χ_{ac,3} signals from the first eleven χ_{ac,3} signals with the smallest value of standard deviation were picked up. Following the same processes, six to nine χ_{ac,3} signals from the eleven χ_{ac,3} signals were finally picked up. In this example, eight χ_{ac,3} signals from the eleven χ_{ac,3} signals were picked up.

Fifthly, the drift in the picked eight χ_{ac,3} signals with time was eliminated via

χ_{ac,4}=χ_{ac,3}−sᵢₙ×t (Equation 3),

where sᵢₙ was the slope of the time dependent picked eight χ_{ac,3} signals at initials. The value of sᵢₙ was obtained by fitting the time dependent picked eight χ_{ac,3} signals at initials to a linear function. The slope of the linear function was sᵢₙ.

In addition, the time dependent χ_{ac,3} signals at terminal sections, which were the last one-fourth part to half part of all sections, were also picked up through a similar way as described above in the fourth step for obtaining χ_{ac,4} signals at initials. For example, the last eleven χ_{ac,3} signals in FIG. 4 were pick up. Then, the standard deviations of ten of the eleven χ_{ac,3} signals were calculated by sequentially neglecting one χ_{ac,3} signal. In this case, eleven values for the standard deviations were gotten. The χ_{ac,3} signal which would lead to the highest value of the standard deviations was removed. Thus, the ten χ_{ac,3} signals from the last eleven χ_{ac,3} signals with the smallest value of standard deviation were picked up. Following the same processes, six to nine χ_{ac,3} signals from the last eleven χ_{ac,3} signals were finally picked up. In this example, eight χ_{ac,3} signals from the last eleven χ_{ac,3} signals were picked up, and were converted to χ_{ac,5} signals via

χ_{ac,5}=χ_{ac,3}−sₜₑ×t (Equation 4)

to eliminate the drift in the picked eight χ_{ac,3} signals with time, where sₜₑ was the slope of the time dependent picked eight χ_{ac,3} signals at terminals. The value of sₜₑ was obtained by fitting the time dependent picked eight χ_{ac,3} signals at terminals to a linear function. The slope of the linear function was sₜₑ.

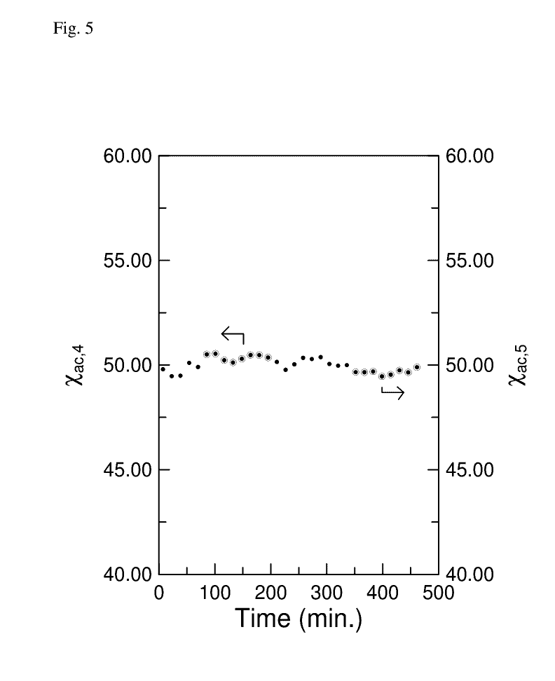

The selected χ_{ac,4}'s and χ_{ac,5}'s in FIG. 4 were circled, as shown in FIG. 5. The mean values of selected χ_{ac,4}'s and χ_{ac,5}'s were calculated and denoted as <χ_{ac,4}> and <χ_{ac,5}> respectively. As compared with FIG. 1, <χ_{ac,4}> was χ_{ac,o} and <χ_{ac,5}> stood for χ_{ac,o}. Thus, the last step was to calculate the IMR signal, IMR(%), via

$$IMR ( \% ) = \frac{〈 {χ}_{a c , 4} 〉 - 〈 {χ}_{a c , 5} 〉}{〈 {χ}_{a c , 4} 〉} \times 100 \% . \qquad ( Equation 5 )$$

For example, the <χ_{ac,4}> in FIG. 5 was 50.35 and <χ_{ac,5}> was 49.64. The IMR signal equaled 1.41%.

One skilled in the art readily appreciates that the present invention is well adapted to carry out the objects and obtain the ends and advantages mentioned, as well as those inherent therein. The methods and uses thereof are representative of preferred embodiments, are exemplary, and are not intended as limitations on the scope of the invention. Modifications therein and other uses will occur to those skilled in the art. These modifications are encompassed within the spirit of the invention and are defined by the scope of the claims.

It will be readily apparent to a person skilled in the art that varying substitutions and modifications may be made to the invention disclosed herein without departing from the scope and spirit of the invention.

All patents and publications mentioned in the specification are indicative of the levels of those of ordinary skill in the art to which the invention pertains. All patents and publications are herein incorporated by reference to the same extent as if each individual publication was specifically and individually indicated to be incorporated by reference.

The invention illustratively described herein suitably may be practiced in the absence of any element or elements, limitation or limitations, which are not specifically disclosed herein. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. A method for calculating the change of signals starting from the originally detected temporal signals (χ), comprising the following steps:
(a) eliminating the drift in the originally detected temporal signals with time to get χᵢ signals;
(b) removing the χᵢ signals existing outside the range of 80% to 120% of the averaged value of all the χᵢ signals to get residual signals as χ₂ signals;
(c) dividing the χ₂ signals into 14-100 sections;
(d) finding the averaged value of the χ₂ signals in each section to get χ₃ signals;
(e) optionally neglecting one or two of the first χ₃ signals and selecting six to nine χ₃ signals with the smallest value of standard deviation in initial sections, wherein the initial sections are the first one-fourth part to half part of all sections;
(f) eliminating the drift in the selected χ₃ signals of step (e) with time to get χ₄ signals;
(g) selecting six to nine χ₃ signals with the smallest value of standard deviation in terminal sections, wherein the terminal sections are the last one-fourth part to half part of all sections;
(h) eliminating the drift in the selected χ₃ signals of step (g) with time to get χ₅ signals; and
(i) finding the difference between the mean values of the χ₄ and χ₅ signals.

2. The method of claim 1, wherein the temporal signals are time dependent ac magnetic signals.

3. The method of claim 1, wherein the change of signals is the reduction in ac magnetic susceptibility of materials.

4. The method of claim 1, wherein the steps of eliminating the drift in the signals with time are done by subtracting each signal by the value lying in the correspondingly linear function.

5. The method of claim 1, wherein the step (b) is removing the χ₁ signals existing outside the range of 90% to 110% of the averaged value of all the χ₁ signals to get residual signals as χ₂ signals.
